(19) United States
(12) Patent Application Publication
(10) Pub. No.: US 2026/0191082 A1
(43) Pub. Date: Jul. 2, 2026

(54) EMBEDDING MEMORY IN INTEGRATED CIRCUIT DEVICE PACKAGES

(71) Applicant: Intel Corporation, Santa Clara, CA (US)

(72) Inventors: Abdallah Bacha, Munich (DE); Bernd Waidhas, Pettendorf (DE); Telesphor Kamgaing, Chandler, AZ (US); Kavitha Nagarajan, Bengaluru (IN); Mohan Prashanth Javare Gowda, Ottobrunn (DE); Klaus Heinz Goebel, Taipei (TW); Han-Wen Lin, Zhubei City (TW); Chee Kheong Yoon, Bayan Lepas (MY)

(73) Assignee: Intel Corporation, Santa Clara, CA (US)

(21) Appl. No.: 19/003,981

(22) Filed: Dec. 27, 2024

(51) Int. Cl. H01L 23/00; H01L 21/56; H01L 23/31; H01L 25/18; H10B 80/00

(52) U.S. Cl. CPC H10W 74/111; H10B 80/00; H10W 90/00; H10W 70/09; H10W 70/60; H10W 74/01; H10W 90/22; H10W 90/26

(57) ABSTRACT

An apparatus is provided which comprises: an interposer comprising traces and conductive contacts on a first interposer surface and a second interposer surface opposite the first interposer surface, a computing device coupled with contacts on the first interposer surface, a first memory array coupled with contacts on the first interposer surface, and a second memory array embedded between the first interposer surface and the second interposer surface, the second memory array inverted in orientation relative to the first memory array, the second memory array directly coupled through traces in the interposer with the first memory array and the computing device. Other embodiments are also disclosed and claimed.

### BACKGROUND

Computing platforms, such as desktops, laptops or smart phones, for example, are expected to have increased performance compared with previous iterations. One way that manufacturers of computing platforms can achieve increased performance is by integrating more integrated circuit devices into a single package. Heterogeneous integration refers to the integration of separately manufactured components into an assembly that, in the aggregate, provides enhanced functionality and improved operating characteristics. As more computing cores are integrated into a package, or system on a chip, there arises a need to integrate more memory components into the package as well. With increased integration, there can arise issues with signal routing and integrity, performance, and circuit board size within device packages. Therefore, there is a need for high performance architectures that address these issues.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIGS. 1A & 1B illustrate a plan view and a cross-sectional view, respectively, of an example embedded memory in an integrated circuit device package, according to some embodiments;

FIG. 2 illustrates a cross-sectional view of an example embedded memory in an integrated circuit device package, according to some embodiments;

FIGS. 3A-3F illustrate cross-sectional views of example manufacturing steps of forming an embedded memory in an integrated circuit device package, according to some embodiments;

FIG. 4 illustrates a cross-sectional view of an example embedded memory in an integrated circuit device package, according to some embodiments;

FIG. 5 illustrates a flowchart of an example method of forming an embedded memory in an integrated circuit device package, in accordance with some embodiments; and

FIG. 6 illustrates a smart device or a computer system or a SoC (System-on-Chip) which includes an embedded memory in an integrated circuit device package, according to some embodiments.

### DETAILED DESCRIPTION

Embedding memory in integrated circuit device packages is generally presented. In this regard, embodiments of the present disclosure enable more memory to be included in close proximity to computing devices/cores. One skilled in the art would appreciate that these interposers with embedded memory may enable higher performance without increasing package dimensions. Additionally, the architectures described herein may offer improved thermal management, signal integrity, and reliability, and thereby enable enhanced features.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “top,” “bottom,” “over,” “under,” and the like in the description and in the claims, if any, are used for descriptive purposes and not necessarily for describing permanent relative positions.

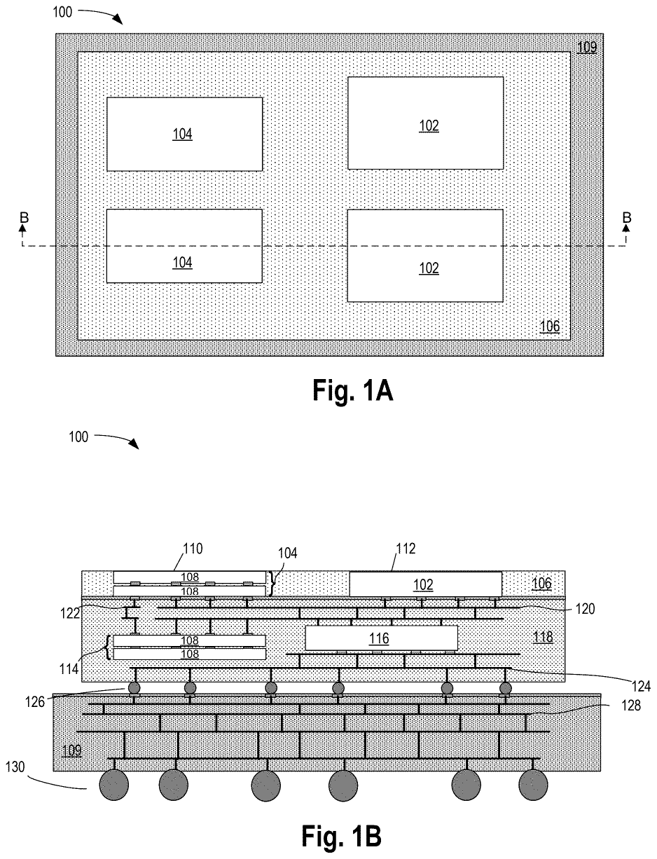

FIGS. 1A & 1B illustrate a plan view and a cross-sectional view, respectively, of an example embedded memory in an integrated circuit device package, according to some embodiments. As shown, device package 100 includes computing devices 102, top memory stacks 104, mold material 106, memory devices 108, package substrate 109, top memory surface 110, computing device surface 112, embedded memory stack 114, embedded hub device 116, interposer 118, upper interposer traces 120, memory connection 122, lower interposer traces 124, micro-bumps 126, substrate traces 128, and package bumps 130. In some embodiments, device package 100 may include additional layers and integrate additional components.

In some embodiments, computing devices 102 may represent controllers, processors, or system-on-a-chip (SOCs), such as multi-core processors, for example. While shown as being discrete devices, computing devices 102 may be implemented as a stack of multiple homogeneous or heterogeneous devices.

In some embodiments, computing devices 102 may be coupled with interposer 118 through traditional solder bonding. In other embodiments, computing devices 102 may be coupled with interposer 118 through hybrid bonding. In some embodiments, computing devices 102 may be coupled with interposer 118 through a direct chip to chip interconnect using high bandwidth interconnect (HBI).

In some embodiments, top memory stacks 104 may include multiple stacks of multiple memory devices 108 communicatively coupled with computing devices 102. In other embodiments, top memory stacks 104 may comprise a single memory device 108.

In some embodiments, memory devices 108 may be discrete memory devices, such as a double data rate (DDR), a high bandwidth memory (HBM), a low power double data rate (LPDDR), or a fast page mode (FPM), for example.

In some embodiments, mold material 106 may be present surrounding computing devices 102 and top memory stacks 104. In some embodiments, mold material 106 may represent an epoxy mold material.

In some embodiments, top memory surface 110 and computing device surface 112 may be coplanar. In other embodiments, top memory surface 110 and computing device surface 112 may be offset by up to 100 microns.

In some embodiments, embedded memory stack 114 may include multiple stacks of multiple memory devices 108 communicatively coupled with computing devices 102. In some embodiments, embedded memory stack 114 may be directly coupled with top memory stack 104 through memory connection 122. In some embodiments, embedded memory stack 114 may include multiple memory devices 108 inverted in orientation relative to memory devices 108 of top memory stack 104. In other words, memory devices 108 of embedded memory stack 114 may include an active surface facing toward an active surface of memory devices 108 of top memory stack 104, and vice versa.

As shown, top memory stack 104 and embedded memory stack 114 include an equal number of memory devices 108, however, in other embodiments they may include disparate numbers of memory devices 108. Also, as shown, top memory stack 104 and embedded memory stack 114 may be in projection with multiple side surfaces of top memory stack 104 coplanar with side surfaces of embedded memory stack 114.

In some embodiments, memory devices 108 in top memory stack 104 and/or embedded memory stack 114 may be coupled through traditional solder bonding. In other embodiments, memory devices 108 in top memory stack 104 and/or embedded memory stack 114 may be coupled through hybrid bonding. In some embodiments, memory devices 108 in top memory stack 104 and/or embedded memory stack 114 may be coupled through a direct chip to chip interconnect using high bandwidth interconnect (HBI).

In some embodiments, embedded memory stack 114 and/or embedded hub device 116 may be placed on a partially formed interposer 118 and then encased a further developed interposer 118. In other embodiments, embedded memory stack 114 and/or embedded hub device 116 may be placed in a cavity formed within interposer 118 by any known method, including, but not limited to, chemical or mechanical etching.

In some embodiments, embedded hub device 116 may represent a component such as an embedded host bridge device. In some embodiments, embedded hub device 116 may a be an embedded multi-die interconnect bridge (EMIB).

In some embodiments, upper interposer traces 120 may include multiple layers of interlayer dielectric, such as organic dielectric, for example, along with metal wires to route between contacts of computing devices 102, top memory stacks 104, embedded memory stack 114, and embedded hub device 116. In some embodiments, lower interposer traces 124 may fan-in a contact pitch from a bottom interposer surface to embedded hub device 116.

In some embodiments, interposer 118 may represent any type of substrate material, including, for example, organic or inorganic materials with or without core layers for mechanical stability. In some embodiments, interposer 118 may include a combination of multiple substrate materials, including silicon with through silicon vias (TSVs).

In some embodiments, interposer 118 may be coupled with package substrate 109 though micro-bumps 126. In other embodiments, however, other interconnect technology may be utilized.

In some embodiments, package substrate 109 may represent any type of substrate material, including, for example, organic or inorganic materials with or without core layers for mechanical stability. In some embodiments, package substrate 109 may include a combination of multiple substrate materials, including silicon with through silicon vias (TSVs).

In some embodiments, substrate traces 128 may include multiple layers of interlayer dielectric, such as organic dielectric, for example, along with metal wires to route between package bumps 130 and micro-bumps 126. In some embodiments, substrate traces 128 may fan-in a contact pitch from package bumps 130 to micro-bumps 126.

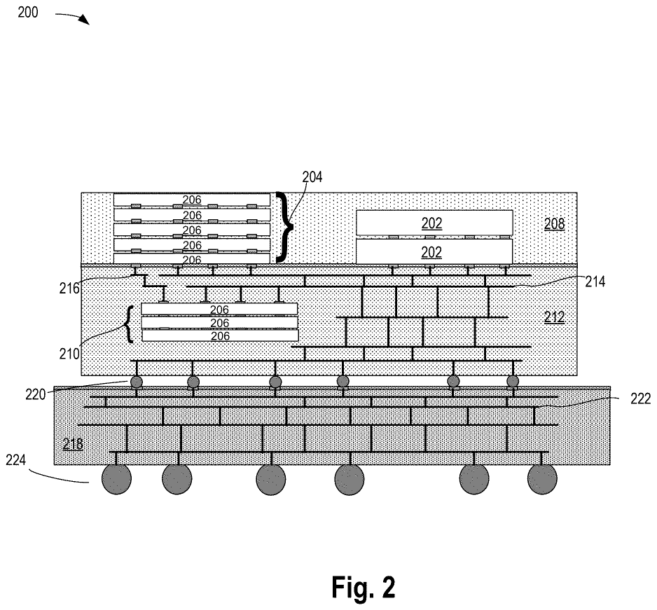

FIG. 2 illustrates a cross-sectional view of an example embedded memory in an integrated circuit device package, according to some embodiments. As shown, device package 200 includes computing devices 202, top memory stack 204, memory devices 206, mold material 208, embedded memory stack 210, interposer 212, interposer traces 214, memory connection 216, package substrate 218, micro-bumps 220, substrate traces 222, and package bumps 224. While shown as including 8 memory devices 206 among top memory stack 204 and embedded memory stack 210, in some embodiments, a different number of memory devices, such as 16 or 32, for example, may be included.

While shown as being out of projection with each other, in some embodiments top memory stack 204 is in projection with embedded memory stack 210. In other embodiments top memory stack 204 and/or embedded memory stack 210 may be spread out across multiple stacks.

In some embodiments, computing devices 202 may be a homogenous stack of processors or other computing devices including two or more computing devices 202. In other embodiments, computing devices 202 may be located side-by-side.

While shown as not including additional embedded components, in some embodiments, interposer 212 and/or package substrate 218 may include multiple additional embedded active and/or passive components.

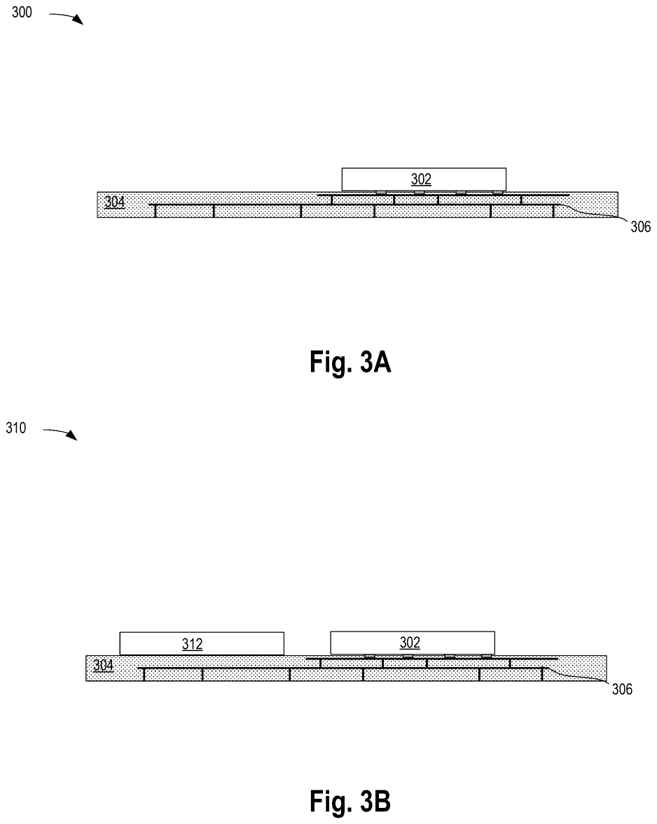

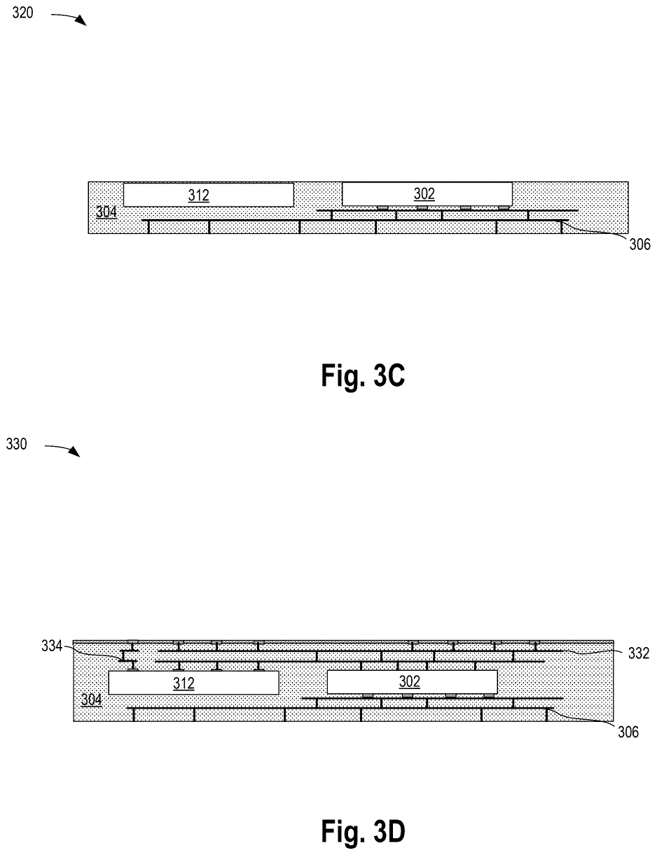

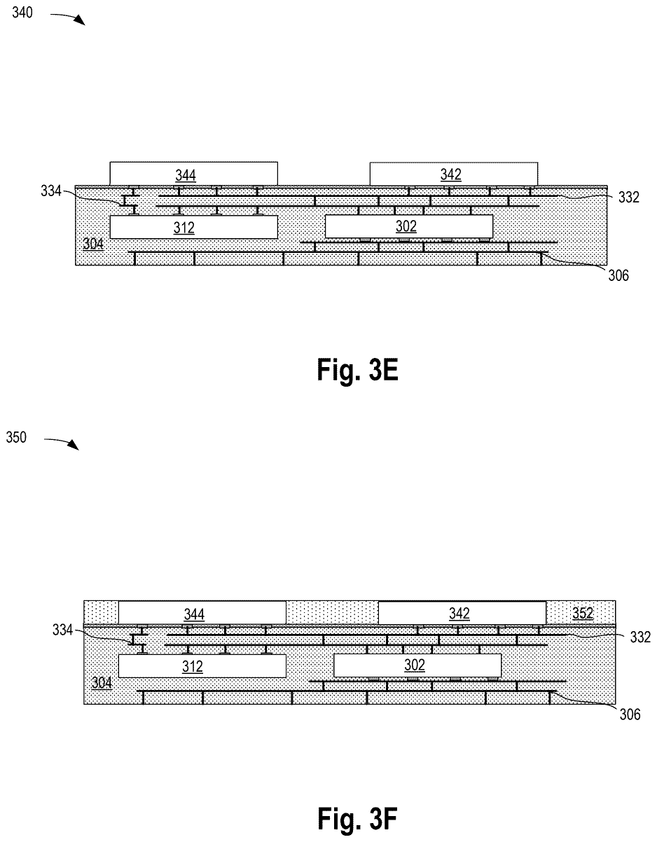

FIGS. 3A-3F illustrate cross-sectional views of example manufacturing steps of forming an embedded memory in an integrated circuit device package, according to some embodiments. As shown in FIG. 3A, assembly 300 includes hub device 302, interposer 304, and traces 306. In some embodiments, interposer 304 may be organic dielectric material insulating conductive traces 306, which may include multiple layers of metal routing, such as copper, and interlayer dielectric to insulate and cover the metal. In some embodiments, hub devices may be soldered to traces 306, including capillary underfill (not shown).

FIG. 3B shows assembly 310, which may include memory 312 on interposer 304. Memory 312 may represent any type of memory device or stack of devices and may be placed inverted with conductive contacts facing away from interposer 304. In some embodiments, adhesive or other filler may be added to secure memory 312 to interposer 304.

As shown in FIG. 3C, assembly 320 includes interposer 304 surrounding memory 312 and hub device 302. In some embodiments, interposer 304 may be a dielectric material deposited by any known technique, including, but not limited to, atomic layer deposition or chemical vapor deposition.

Turning now to FIG. 3D, assembly 330 may include upper traces 332 and memory connection 334 formed in further developed interposer 304. In some embodiments, upper traces 332 conductively couple memory 312 and hub device 302.

FIG. 3E shows assembly 340, which may include computing device 342 and memory 344. In some embodiments, memory 344 and memory 312 are in projection with each other and are directly connected through memory connection 334. In some embodiments,

computing device 342 is conductively coupled with memory 344, memory 312, and hub device 302 through upper traces 332.

As shown in FIG. 3F, assembly 350 may include mold material 352 surrounding computing device 342 and memory 344. In some embodiments, mold material 352 may be an epoxy mold deposited by any known method.

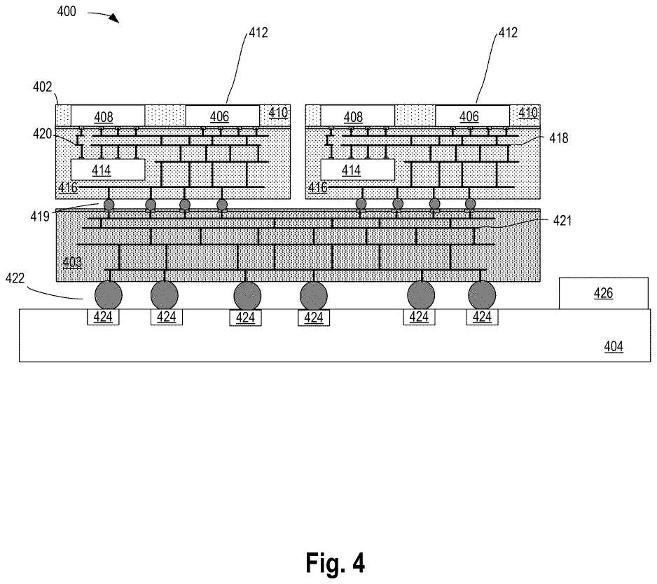

FIG. 4 illustrates a cross-sectional view of an example embedded memory in an integrated circuit device package, according to some embodiments. As shown, assembly 400 includes device package 402, package substrate 403, system board 404, computing device 406, top memory array 408, mold material 410, coplanar surface 412, embedded memory array 414, interposer 416, interposer traces 418, micro-bumps 419, memory connection 420, substrate traces 421, solder balls 422, board pads 424, and board component 426.

Device package 402 may incorporate elements previously discussed in reference to prior figures. For example, device package 402 may have properties discussed in reference to FIGS. 1A-B, 2, or 3A-3F. As shown, device package 402 may include top memory array 408 in projection with embedded memory array 414, which may include an equal or disparate number of memory devices. Device package 402 may include other devices in other configurations, for example, multiple integrated circuit devices coupled through an embedded multi-die interconnect bridge.

In some embodiments, solder balls 422 may be formed on a device package substrate surface, thereby allowing device package 402 to be soldered to system board 404 through board pads 424. System board 404 may also incorporate board component 426, which may represent any type of active or passive system components, such as a power supply, memory devices, voltage regulators, I/O interfaces, etc.

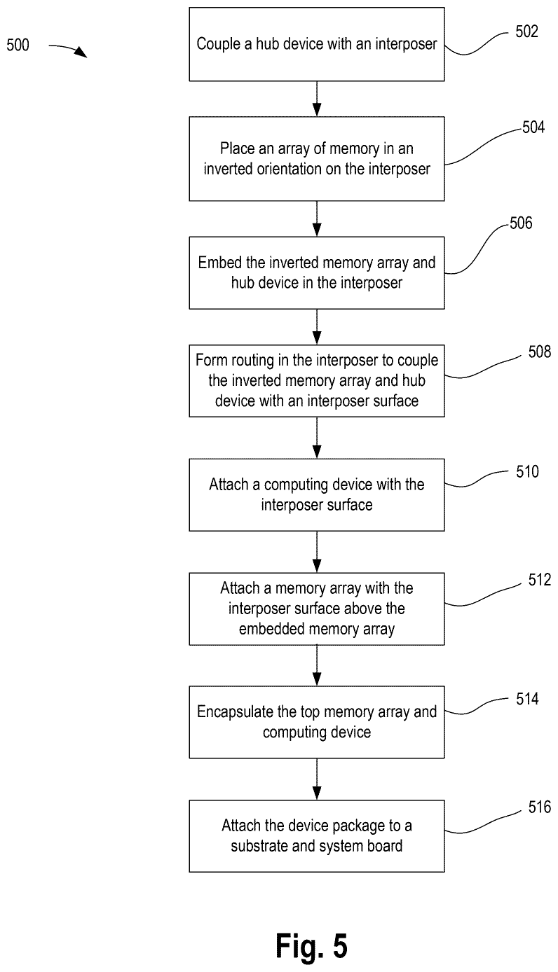

FIG. 5 illustrates a flowchart of an example method of forming an embedded memory in an integrated circuit device package, in accordance with some embodiments. Although the blocks in the flowchart with reference to FIG. 5 are shown in a particular order, the order of the actions can be modified. Thus, the illustrated embodiments can be performed in a different order, and some actions/blocks may be performed in parallel. Some of the blocks and/or operations listed in FIG. 5 are optional in accordance with certain embodiments. The numbering of the blocks presented is for the sake of clarity and is not intended to prescribe an order of operations in which the various blocks must occur. Additionally, operations from the various flows may be utilized in a variety of combinations.

Method 500 begins with coupling (502) a hub device with an interposer substrate. In some embodiments, such as assembly 300, hub device 302 may be soldered with conductive traces 306. Next, an array of memory is placed (504) in an inverted orientation on the interposer. In some embodiments, such as assembly 310, memory 312 may be placed on interposer 304.

Then, the inverted memory array and hub device may be embedded (506) in the interposer. In some embodiments, such as assembly 320, interposer 304 may be deposited by any known method around memory 312 and hub device 302. Next, routing may be formed (508) in the interposer to couple the inverted memory array and hub device with an interposer surface. In some embodiments, such as assembly 330, conductive traces 332 may be formed over, and in contact with, memory 312 and hub device 302, by any known method.

The method continues, in some embodiments, with attaching (510) a computing device with the interposer surface. In some embodiments, such as assembly 340, computing device 342 may be bonded to the interposer surface, for example through soldering. Next, a memory array may be attached (512) with the interposer surface above the embedded memory array. In some embodiments, such as assembly 340, memory 344 may be bonded to the interposer surface, for example through soldering.

Next, the top memory array and computing device may be encapsulated (514) with mold material. In some embodiments, such as assembly 350, mold material 352 may be deposited surrounding memory 344 and computing device 342 by any known method. Finally, the device package may be attached (516) to a system board. In some embodiments, such as assembly 400, device package 402 may be attached to system board 404.

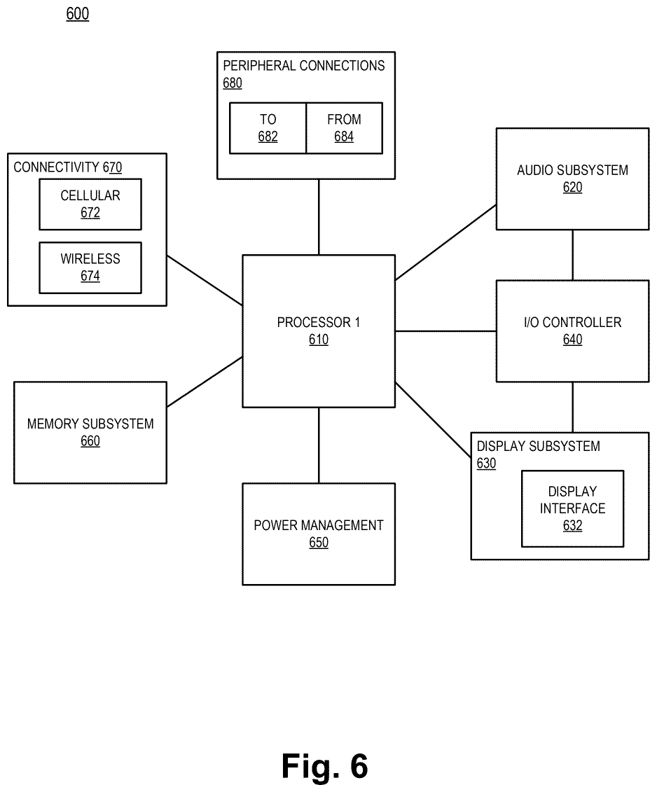

FIG. 6 illustrates a smart device or a computer system or a SoC (System-on-Chip) which includes an embedded memory in an integrated circuit device package, according to some embodiments. In some embodiments, computing device 600 represents a mobile computing device, such as a computing tablet, a mobile phone or smart-phone, a wireless-enabled e-reader, or other wireless mobile device. It will be understood that certain components are shown generally, and not all components of such a device are shown in computing device 600. In some embodiments, one or more components of computing device 600, for example processor 610 or I/O controller 640, include an embedded memory in an integrated circuit device package as described above.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, etc., may be used without departing from the scope of the disclosure.

In some embodiments, computing device 600 includes a first processor 610. The various embodiments of the present disclosure may also comprise a network interface within 670 such as a wireless interface so that a system embodiment may be incorporated into a wireless device, for example, cell phone or personal digital assistant.

In one embodiment, processor 610 can include one or more physical devices, such as microprocessors, application processors, microcontrollers, programmable logic devices, or other processing means. The processing operations performed by processor 610 include the execution of an operating platform or operating system on which applications and/or device functions are executed. The processing operations include operations related to I/O (input/output) with a human user or with other devices, operations related to power management, and/or operations related to connecting the computing device 600 to another device. The processing operations may also include operations related to audio I/O and/or display I/O.

In one embodiment, computing device 600 includes audio subsystem 620, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 600, or connected to the computing device 600. In one embodiment, a user interacts with the computing device 600 by providing audio commands that are received and processed by processor 610.

Display subsystem 630 represents hardware (e.g., display devices) and software (e.g., drivers) components that provide a visual and/or tactile display for a user to interact with the computing device 600. Display subsystem 630 includes display interface 632, which includes the particular screen or hardware device used to provide a display to a user. In one embodiment, display interface 632 includes logic separate from processor 610 to perform at least some processing related to the display. In one embodiment, display subsystem 630 includes a touch screen (or touch pad) device that provides both output and input to a user.

I/O controller 640 represents hardware devices and software components related to interaction with a user. I/O controller 640 is operable to manage hardware that is part of audio subsystem 620 and/or display subsystem 630. Additionally, I/O controller 640 illustrates a connection point for additional devices that connect to computing device 600 through which a user might interact with the system. For example, devices that can be attached to the computing device 600 might include microphone devices, speaker or stereo systems, video systems or other display devices, keyboard or keypad devices, or other I/O devices for use with specific applications such as card readers or other devices.

As mentioned above, I/O controller 640 can interact with audio subsystem 620 and/or display subsystem 630. For example, input through a microphone or other audio device can provide input or commands for one or more applications or functions of the computing device 600. Additionally, audio output can be provided instead of, or in addition to display output. In another example, if display subsystem 630 includes a touch screen, the display device also acts as an input device, which can be at least partially managed by I/O controller 640. There can also be additional buttons or switches on the computing device 600 to provide I/O functions managed by I/O controller 640.

In one embodiment, I/O controller 640 manages devices such as accelerometers, cameras, light sensors or other environmental sensors, or other hardware that can be included in the computing device 600. The input can be part of direct user interaction, as well as providing environmental input to the system to influence its operations (such as filtering for noise, adjusting displays for brightness detection, applying a flash for a camera, or other features).

In one embodiment, computing device 600 includes power management 650 that manages battery power usage, charging of the battery, and features related to power saving operation. Memory subsystem 660 includes memory devices for storing information in computing device 600. Memory can include nonvolatile (state does not change if power to the memory device is interrupted) and/or volatile (state is indeterminate if power to the memory device is interrupted) memory devices. Memory subsystem 660 can store application data, user data, music, photos, documents, or other data, as well as system data (whether long-term or temporary) related to the execution of the applications and functions of the computing device 600.

Elements of embodiments are also provided as a machine-readable medium (e.g., memory 660) for storing the computer-executable instructions. The machine-readable medium (e.g., memory 660) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 670 includes hardware devices (e.g., wireless and/or wired connectors and communication hardware) and software components (e.g., drivers, protocol stacks) to enable the computing device 600 to communicate with external devices. The computing device 600 could be separate devices, such as other computing devices, wireless access points or base stations, as well as peripherals such as headsets, printers, or other devices.

Connectivity 670 can include multiple different types of connectivity. To generalize, the computing device 600 is illustrated with cellular connectivity 672 and wireless connectivity 674. Cellular connectivity 672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 674 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 680 include hardware interfaces and connectors, as well as software components (e.g., drivers, protocol stacks) to make peripheral connections. It will be understood that the computing device 600 could both be a peripheral device (“to” 682) to other computing devices, as well as have peripheral devices (“from” 684) connected to it. The computing device 600 commonly has a “docking” connector to connect to other computing devices for purposes such as managing (e.g., downloading and/or uploading, changing, synchronizing) content on computing device 600. Additionally, a docking connector can allow computing device 600 to connect to certain peripherals that allow the computing device 600 to control content output, for example, to audiovisual or other systems.

In addition to a proprietary docking connector or other proprietary connection hardware, the computing device 600 can make peripheral connections 680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. An apparatus comprising:
an interposer comprising traces and conductive contacts on a first interposer surface and a second interposer surface opposite the first interposer surface;
a computing device coupled with contacts on the first interposer surface;
a first memory array coupled with contacts on the first interposer surface; and
a second memory array embedded between the first interposer surface and the second interposer surface, the second memory array inverted in orientation relative to the first memory array, the second memory array directly coupled through traces in the interposer with the first memory array and the computing device.

2. The apparatus of claim 1, wherein the first memory array is in projection with the second memory array.

3. The apparatus of claim 1, wherein the first memory array and the second memory array both comprise a same quantity of discrete devices.

4. The apparatus of claim 1, wherein the first memory array and the second memory array comprise a memory technology chosen from the group consisting of: double data rate (DDR), high bandwidth memory (HBM), low power double data rate (LPDDR), and fast page mode (FPM).

5. The apparatus of claim 1, wherein the first memory array includes surfaces coplanar with surfaces of the computing device.

6. The apparatus of claim 1, wherein the first memory array comprises separate coplanar stacks of memory devices.

7. The apparatus of claim 1, wherein the first memory array and the second memory array together comprise eight discrete devices.

8. A system comprising:
a host board;
an integrated circuit device package, the integrated circuit device package comprising:
an interposer comprising traces and conductive contacts on a first interposer surface and a second interposer surface opposite the first interposer surface;
a computing device coupled with contacts on the first interposer surface;
a first memory array coupled with contacts on the first interposer surface;
a communication device embedded between the first interposer surface and the second interposer surface; and
a second memory array embedded between the first interposer surface and the second interposer surface, the second memory array inverted in orientation relative to the first memory array, the second memory array directly coupled through traces in the interposer with the first memory array and the communication device; and
a power supply to provide power to the integrated circuit device package through the host board.

9. The system of claim 8, wherein the first memory array is in projection with the second memory array.

10. The system of claim 8, wherein the first memory array and the second memory array both comprise a same quantity of discrete devices.

11. The system of claim 8, wherein the first memory array and the second memory array comprise a memory technology chosen from the group consisting of: double data rate (DDR), high bandwidth memory (HBM), low power double data rate (LPDDR), and fast page mode (FPM).

12. The system of claim 8, wherein the first memory array includes surfaces coplanar with surfaces of the computing device.

13. The system of claim 8, wherein the first memory array comprises separate coplanar stacks of memory devices.

14. The system of claim 8, wherein the second memory array includes a surface coplanar with a surface of the communication device.

15. A method comprising:
forming an interposer comprising traces and conductive contacts on a first interposer surface and a second interposer surface opposite the first interposer surface;
embedding a first memory in the interposer between the first interposer surface and the second interposer surface;
coupling a second memory with contacts on the first interposer surface;
coupling a computing device with contacts on the first interposer surface; and
embedding a hub device in the interposer between the first interposer surface and the second interposer surface.

16. The method of claim 15, wherein embedding a first memory comprises embedding a memory device in an inverted orientation relative to the second memory.

17. The method of claim 15, wherein attaching a second memory comprises attaching multiple coplanar stacks of memory devices.

18. The method of claim 15, wherein attaching a second memory comprises attaching the second memory in projection with the first memory.

19. The method of claim 15, wherein embedding a hub device comprises embedding the hub device in the interposer coplanar with the first memory.

20. The method of claim 15, further comprising encapsulating the second memory and the computing device.
